(19) United States
(12) Patent Application Publication
(10) Pub. No.: US 2003/0008532 A1
(43) Pub. Date: Jan. 9, 2003

(54) Method and apparatus for increasing flow capacity associated with a valve

(76) Inventors: Bau-San Yuan, San Jose, CA (US); Martin E. Lee, Saratoga, CA (US); Ed. E. Reynolds, Foster City, CA (US)

Correspondence Address: RITTER, LANG & KAPLAN, 12930 SARATOGA AE. SUITE D1, SARATOGA, CA, 95070, US

(21) Appl. No.: 09/902,063

(22) Filed: Jul. 9, 2001

(51) Int. Cl. H01L 21/00

(52) U.S. Cl. 438/800

(57) ABSTRACT

Methods and apparatus for efficiently compensating for pressure changes in a active vibration isolation system are disclosed. According to one aspect of the present system, system that reduces the vibrations experienced by a mass includes a chamber that supports the mass, a control device, a valve mechanism, and a bypass mechanism. The control device monitors a pressure level within the chamber. The valve mechanism includes a first flow path that is in fluid communication with the chamber. The valve mechanism also alters a capacity of the first flow path in response to a control signal generated by the controller. Finally, the bypass mechanism defines a second flow path that enables fluid to flows through the second flow path into the chamber. The second flow path is parallel to the first flow path to enable parallel fluid flow to occur.

### BACKGROUND OF THE INVENTION

1. Field of Invention

The present invention relates generally to controlling vibrations in mechanical systems using controlled valve mechanisms. More particularly, the present invention relates to a valve bypass arrangement which effectively increases the flow capacity associated with a controlled valve in a vibration control system to enable vibrations to be efficiently controlled and dampened.

2. Description of the Related Art

For precision instruments such as photolithography machines which are used in semiconductor processing, factors which affect the performance, e.g., accuracy, of the precisions instruments generally must be dealt with and, insofar as possible, eliminated. When the performance of a precision instrument is adversely affected, as for example by vibrations, products formed using the precision instrument may be improperly formed and, hence, defective. For instance, a photolithography machine which is subjected to vibratory motion may cause an image projected by the photolithography machine to move, and, as a result, be aligned incorrectly on a projection surface such as a semiconductor wafer.

An active vibration isolation system (AVIS) is an example of a system which is used to compensate for vibrations which may be experienced by a device such as a photolithography machine. An AVIS effectively “floats” the photolithography machine on an air cushion such that vibrations in the photolithography machine, as well as external vibrations such as vibrations passed through a floor surface, may be compensated for by the AVIS.

FIG. 1 is a diagrammatic representation of a chamber that is a part of a conventional AVIS. An AVIS 102 includes a chamber 106 and a membrane 110. Membrane 110 is arranged to support a force 112 such as a force associated with a photolithography machine, as well as vibrational and gravity forces. That is, membrane 110 is arranged to carry a load associated with, for example, the photolithography machine (not shown). Chamber 106 is typically pressurized through an inlet 116. The pressure level in chamber 106 may be varied to flex membrane 110 such that a position of the photolithography machine, i.e., a position with respect to a z-direction 120, remains essentially constant. Varying the pressure level enables membrane 110 to support force 112 such that any vibrational forces are dampened.

AVIS 102 generally controls vibrations associated with force 112, i.e., vibrational forces on the photolithography machine, by adjusting the pressure within chamber 106. FIG. 2a is a block diagram representation of a control system which enables the pressure within a chamber to be adjusted. A system 202 includes a chamber 206, a controller 210, and an air supply 214. Controller 210 may monitor a pressure level in chamber 206, and when it is determined by controller 210 that the pressure level in chamber 206 is to be altered, controller 210 may generally alter an amount of compressed air supplied by air supply 214 to chamber 206. Altering the amount of air may include altering the flow rate of air into diaphragm chamber 206 such that the pressure level diaphragm chamber 206.

Typically, a valve or a similar device may be used to control the amount of air which is allowed into chamber 206. With reference to FIG. 2b, a control system which includes a solenoid and a valve for controlling air flow into chamber 206 will be described. A valve 240, which may be a three-way valve, is coupled to air supply 214, chamber 206, and a solenoid 246. Solenoid 246 is controlled by controller 210 such that solenoid 246 alters the flow rate of air which passes out of valve 240 and into chamber 206. Solenoid 246 often adjusts the air flow into chamber 206 by controlling the amount of air which is effectively removed from valve 240 such that the air does not pass into chamber 206.

While the use of solenoid 246 and valve 240 is effective in controlling the pressure in chamber 206, solenoid 246 and valve 240 generally have a response time that is relatively slow. That is, the response time of solenoid 246 and valve 240 may be such that an unacceptable amount of vibrations may be felt by a device supported by chamber 206 while valve 240 is in the process of being adjusted. Solenoid 246 behaves like an on/off switch such that the response time is typically a result of the response time of solenoid 246, and the amount of time needed by valve 240 to reach an equilibrium with respect to the flow out of valve 240 and into chamber 206. The amount of time needed by valve 240 to achieve a desired flow capacity is often a result of the maximum flow capacity associated with valve 240.

Therefore, what is needed is a method and an apparatus which enables the pressure to be effectively maintained at a desired level or adjusted to a desired level within a chamber that is part of an AVIS. Specifically, what is needed is a method and an apparatus which enables the response time associated with using a valve to achieve a desired pressure level in a chamber to be improved.

### SUMMARY OF THE INVENTION

The present invention relates to a control system which includes a valve and has a relatively fast response to compensating for vibrations. According to one aspect of the present system, an active vibration isolation system that reduces the vibrations experienced by a mass includes a chamber, a control device, a valve mechanism, and a bypass mechanism. The chamber includes a surface that supports the mass. The control device monitors a pressure level within the chamber, and also generates a control signal. The valve mechanism includes a first flow path that is in fluid communication with or is fluidly coupled to the chamber such that fluid may flow between the first flow path and the chamber. The valve mechanism also alters a flow capacity of the first flow path in response to the control signal. Finally, the bypass mechanism effectively defines a second flow path that is in fluid communication with the chamber such that fluid flows through the second flow path and into the chamber. The second flow path is substantially parallel to the first flow path to enable parallel fluid flow to occur in the second flow path and the first flow path. The flow capacity of the second flow path is greater than the flow capacity of the first flow path.

In one embodiment, the fluid that flows between the first flow path and the chamber and the fluid that flows through the second flow path and into the chamber cooperate to maintain the pressure level within the chamber at a predetermined level. In another embodiment, the bypass mechanism includes a valve which allows the flow capacity of the second flow path to be altered.

The use of a bypass mechanism in conjunction with a controlled valve enables the response time associated with compensating for vibrations to be reduced. Hence, the performance of an overall control system may be improved. The pressure capacity or flow capacity of most valves may effectively be improved through the use of a bypass mechanism which provides a flow path that is parallel to the flow path of the valve. The response associated with requests to change the flow rate or flow capacity of fluid through a valve may be relatively slow when vibrations which are to be compensated for are over approximately one hertz, and a substantial portion of the flow is to occur through the valve. The use of the bypass to accommodate most of the flow, and the use of the valve to accommodate a relatively small portion of the flow, enables changes to the flow in response to vibrations to occur relatively quickly.

According to another aspect of the present invention, a control system includes a fluid supply that supplies fluid, e.g., compressed fluid, to a device that includes a device inlet and a chamber which is pressurized by the fluid provided by the fluid supply. A controller mechanism, which monitors the pressure within the chamber, also communicates with a valve mechanism that is fluidly coupled to the fluid supply and the device in order to at least partially control flow of the fluid through the valve mechanism. The control system also includes a bypass mechanism that is fluidly coupled to both the fluid supply and the device. The bypass mechanism and the valve mechanism being arranged to provide substantially parallel flow paths between the fluid supply and the device such that fluid may flow through both flow paths substantially simultaneously. The flow rate of fluid passing from the bypass mechanism to the device is substantially higher than a flow rate of fluid passing from the valve mechanism to the device. In one embodiment, the bypass mechanism includes a flow adjuster that controls the flow rate of the fluid passing from the bypass mechanism to the device.

In another embodiment, the valve mechanism includes or defines a flow path, and the control mechanism is arranged to control the valve mechanism to increase the flow of fluid through the flow path. In such an embodiment, the control mechanism may also be arranged to control the valve mechanism to decrease the flow of fluid through the flow path.

According to still another aspect of the present invention, a method for operating a control device that includes a chamber, a control device, a valve mechanism, and a bypass includes providing a first amount of fluid to the chamber through the valve mechanism and providing a second amount of fluid to the chamber through the bypass. The second amount of fluid is substantially greater than the first amount of fluid. A determination is made as to when a change in a pressure level within the chamber has been detected by the control device. If a change in the pressure level within the chamber has been detected by the control device, the valve mechanism adjusts the first amount of fluid using the control device, and the adjusted first amount of fluid is provided to the chamber through the valve mechanism to compensate for the change in the pressure level within the chamber. The second amount of fluid provided to the chamber through the bypass continues to be provided while the adjusted first amount of fluid is provided to the chamber.

These and other advantages of the present invention will become apparent upon reading the following detailed descriptions and studying the various figures of the drawings.

### BRIEF DESCRIPTION OF THE DRAWINGS

The invention may best be understood by reference to the following description taken in conjunction with the accompanying drawings in which:

FIG. 1 is a diagrammatic representation of a chamber which is a part of an active vibration isolation system.

FIG. 2a is a block diagram representation of a conventional system for controlling air flow into a diaphragm system.

FIG. 2b is a block diagram representation of a conventional system which includes a solenoid and a valve for controlling air flow into a diaphragm system.

FIG. 3 is a block diagram representation of a first system for controlling air flow into a diaphragm system in accordance with an embodiment of the present invention.

FIG. 4 is a block diagram representation of a second system for controlling air flow into a diaphragm system in accordance with an embodiment of the present invention.

FIG. 5 is a block diagram representation of a system which includes a valve with a voice coil motor and a bypass flow mechanism in accordance with an embodiment of the present invention.

FIG. 6 is a process flow diagram which illustrates the steps associated with configuring a vibration control system in accordance with an embodiment of the present invention.

FIG. 7 is a process flow diagram which illustrates the steps associated with the operation of a vibration control system that includes a valve mechanism and a valve bypass in accordance with an embodiment of the present invention.

FIG. 8 is a process flow diagram which illustrates the steps associated with adjusting flow through a valve mechanism, i.e., step 718 of FIG. 7, in accordance with an embodiment of the present invention.

FIG. 9 is a diagrammatic representation of a photolithography apparatus which has vibrations that may be dampened by a diaphragm chamber in accordance with an embodiment of the present invention.

FIG. 10 is a process flow diagram which illustrates the steps associated with fabricating a semiconductor device in accordance with an embodiment of the present invention.

FIG. 11 is a process flow diagram which illustrates the steps associated with processing a wafer, i.e., step 1304 of FIG. 10, in accordance with an embodiment of the present invention.

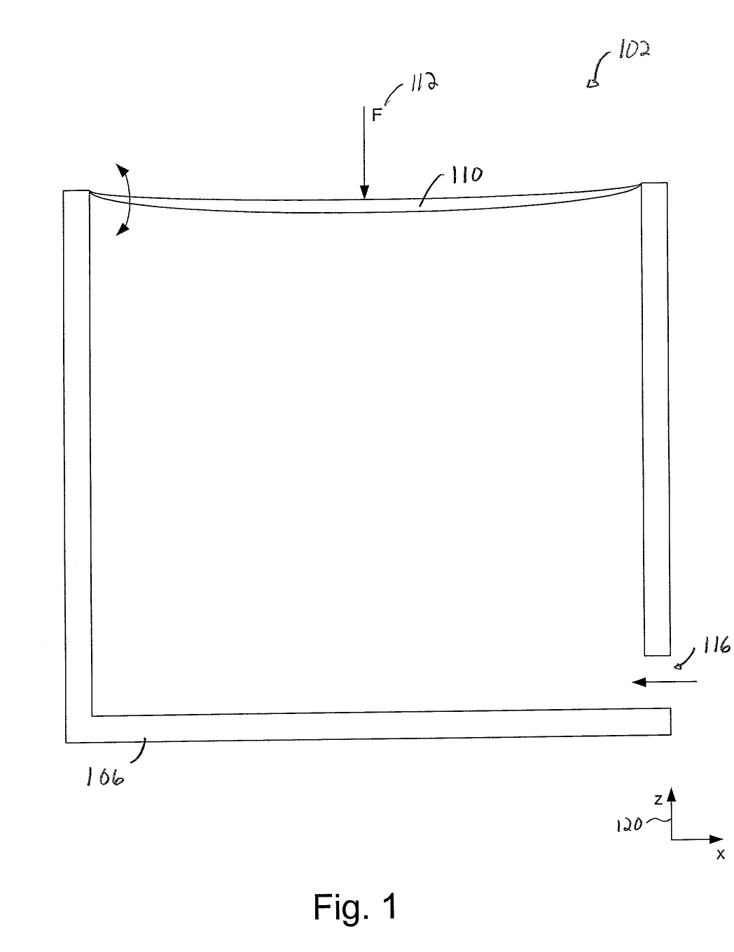

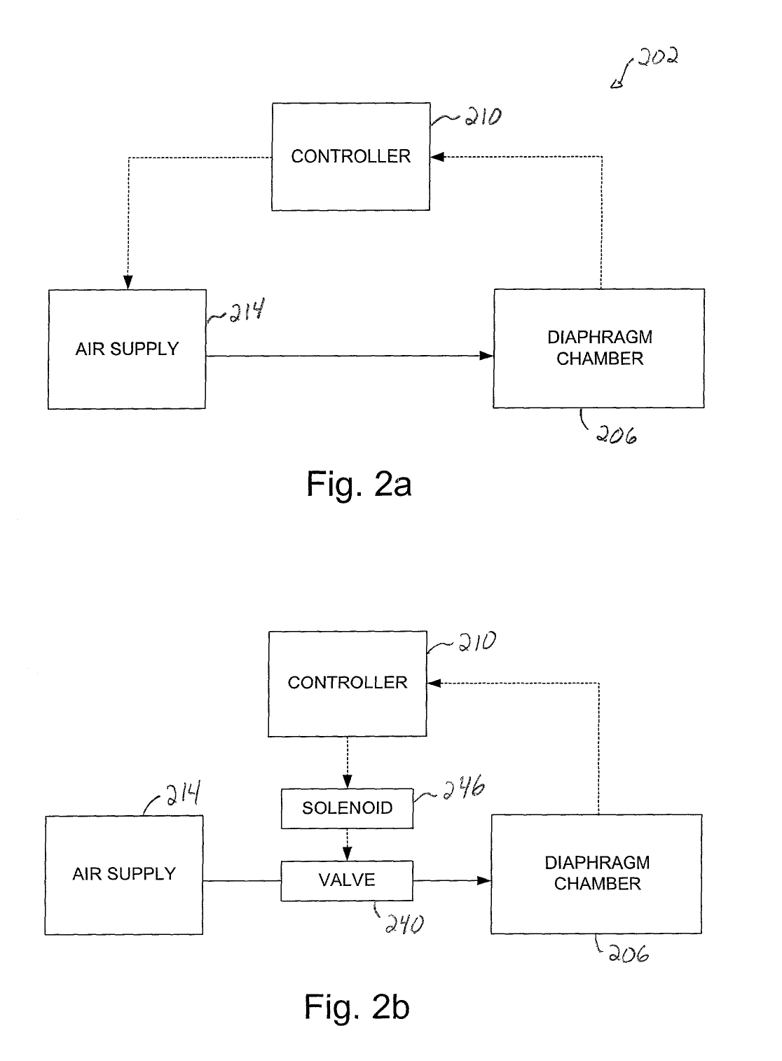

### DETAILED DESCRIPTION OF THE EMBODIMENTS

In order to effectively increase the flow capacity associated with a controlled valve, the limited pressure capacity or the limited flow capacity of the valve may be augmented by providing an alternate flow path to the flow path associated with the valve. Implementing a bypass or a shunt with respect to a valve enables the flow of air through the valve to be augmented by the flow of air through the bypass. As such, the flow rate or the flow capacity associated with the valve is effectively increased, while the flow may be fine tuned, or adjusted, relatively quickly through the use of the controlled valve. That is, the bulk of air flow provided to a chamber may be provided through the bypass, while a substantially smaller, readily controllable amount may be provided to the chamber through the valve. Hence, the use of a bypass allows for a faster response to a change in the pressure level in the chamber by enabling changes to the pressure level to be accommodated by the valve, while the majority of the pressure level is maintained through the bypass. The faster response is due, at least in part, to the fact that the majority of the flow of air is not altered by the valve.

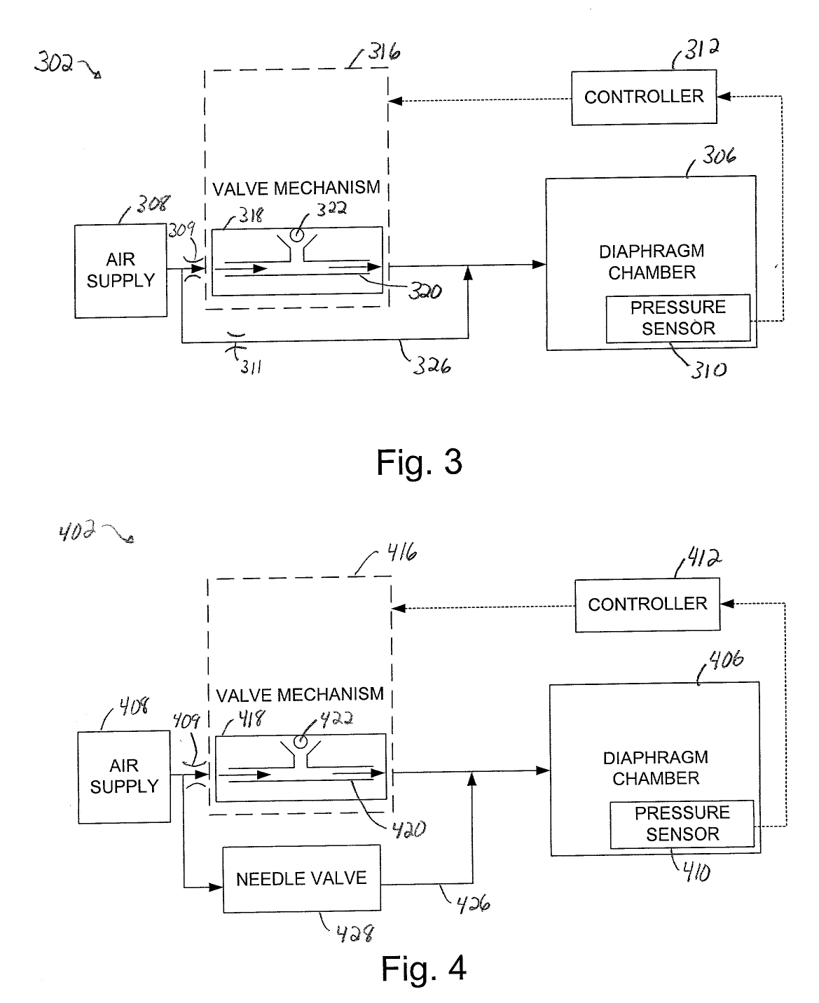

With reference to FIG. 3, a bypass or shunt which effectively increases the flow rate associated with a controlled valve will be described in accordance with an embodiment of the present invention. FIG. 3 is a representation of an active vibration isolation system (AVIS) which is controlled by a controlled valve that is augmented by a fluid flow bypass. As one embodiment of an AVIS includes a chamber and a diaphragm, herein and after, an AVIS will be referred to as a diaphragm chamber. A vibration control system 302 includes a diaphragm chamber 306 which is pressurized using air, or a gas, provided through a flow restrictor 309 by an air supply 308. Typically, air supply 308 is arranged to supply compressed air. The amount of air which is needed to provide diaphragm chamber 306 with the pressure necessary to compensate for vibrational effects on a device (not shown) supported on diaphragm chamber is regulated at least in part by a controller 312.

Controller 312, which receives pressure readings relating to the pressure within diaphragm chamber 306 from a pressure sensor 310 associated with diaphragm chamber 306, controls a valve mechanism 316. In one embodiment, pressure sensor 310 provides feedback signals which controller 312 processes. Although valve mechanism 316 may be substantially any type of valve, in one embodiment, valve mechanism 316 includes a body 318. Body 318 includes a flow path 320 which is fluidly coupled on one end to air supply 308 through flow restrictor 309, and fluidly coupled on another end to diaphragm chamber 306. Body 318 also includes or is coupled to a bleed control mechanism 322 which, as shown, may be a bleed control ball that may effectively be retracted from or drawn into a funnel arrangement as appropriate to effectively control the amount of air flow through flow path 320. In other words, the position of a bleed control ball may be controlled to control the amount of flow obstruction the bleed control ball causes with respect to the funnel arrangement. Bleed control mechanism 322 is arranged to “bleed off” air from flow path 320 in order to control the flow rate of air through flow path 320. Hence, air that flows into flow path 320 either flows out of flow path 320 and into diaphragm chamber 306, or is bled off through bleed control mechanism 322.

A bypass 326, which may be formed from a conduit or pipe, may include a fixed flow restrictor 311, and is arranged to substantially directly couple air supply 308 to diaphragm chamber 306. In other words, bypass 326 serves as a shunt to carry air from air supply 308 to diaphragm chamber 306 without passing through valve mechanism 316. Typically, bypass 326 provides a flow path which operates in parallel with flow path 320 such that between air supply 308 and diaphragm chamber 306, the majority of air passes through bypass 326 while some air passes through flow path 320. The parallel air flow, or the substantially simultaneous air flow, which occurs in bypass 326 and flow path 320 enables the flow capacity of bypass 326 to essentially be augmented by the flow capacity of flow path 320. Flow restrictor 309 is arranged to restrict the flow of air into valve mechanism 316, i.e., flow restrictor 309 causes air to flow through bypass 326. Typically, flow restrictor 309 is fixed, although it should be appreciated that in one embodiment, flow restrictor 309 may be adjustable.

As will be appreciated by those skilled in the art, the flow rate of air passing through bypass 326 is generally higher than the flow rate of air passing through valve mechanism 316, i.e., through flow path 320. By way of example, the flow rate of air through bypass 326 may be an order of magnitude higher than the flow rate of air through valve mechanism 316. Typically, the flow volume through bypass 326 is also substantially higher than the flow volume through valve mechanism 316. Hence, the majority of the pressure level in diaphragm chamber 306 is maintained by air obtained through bypass 326.

By adjusting the amount of air which successfully flows through flow path 320, i.e., air which passes through flow path 320 and is not bled off through bleed control mechanism 322, the pressure maintained within diaphragm chamber 306 may be “fine tuned.” That is, relatively small changes in pressure may be made relatively quickly through flow path 320. For example, if the pressure level in diaphragm chamber 306 is to be lowered, then bleed control mechanism 322 may be configured to enable more air to be bled off from flow path 320. Alternatively, when the pressure level in diaphragm chamber 306 is to be raised, then bleed control mechanism 322 may be configured to enable less air to be bled off from flow path 320.

The size of bypass 326, e.g., the inner diameter of bypass 326 when bypass 326 is a pipe such as a rubber or plastic pipe with a substantially circular cross-section, is typically chosen such that a desired flow rate may be maintained through bypass 326. In other words, the size of bypass 326 is often chosen such that air flow from air supply 308 through bypass 326 is able to substantially maintain a desired pressure level within diaphragm chamber 306. As a result, once the pressure level which is expected to be maintained, or the ambient pressure level, in diaphragm chamber 306 is identified, the size of bypass 326 may be determined using factors that include, but are not limited to, the expected pressure level of the diaphragm chamber and the pressure associated with air supply 308.

When it is anticipated that different pressure levels may be maintained within diaphragm chamber 306 for different purposes and, hence, that bypasses of different sizes may be needed, an adjustable bypass may be utilized to provide air flow into diaphragm chamber. Although selecting bypass 326 based upon a desired pressure level is effective, creating different bypasses, and implementing the different bypasses in vibration control system 302, may be time-consuming. Allowing the amount of flow through a bypass to be adjustable enables a single adjustable bypass to support multiple pressure levels.

FIG. 4 is a block diagram representation of a vibration control system with an adjustable bypass in accordance with an embodiment of the present invention. A vibration control system 402 includes a diaphragm chamber 406 which is pressurized using air provided by an air supply 408. The amount of air which is needed to provide diaphragm chamber 406 with the pressure necessary to compensate for vibrational effects, e.g., relatively high frequency vibrational effects, on a device (not shown) supported on a diaphragm of diaphragm chamber 406 is effectively regulated by a controller 412. Controller 412 receives pressure readings relating to the pressure within diaphragm chamber 406 from a pressure sensor 410 which monitors pressure within diaphragm chamber 406. Using pressure readings which may either be feedforward signals or feedback signals, controller 412 controls the operation of a valve mechanism 416.

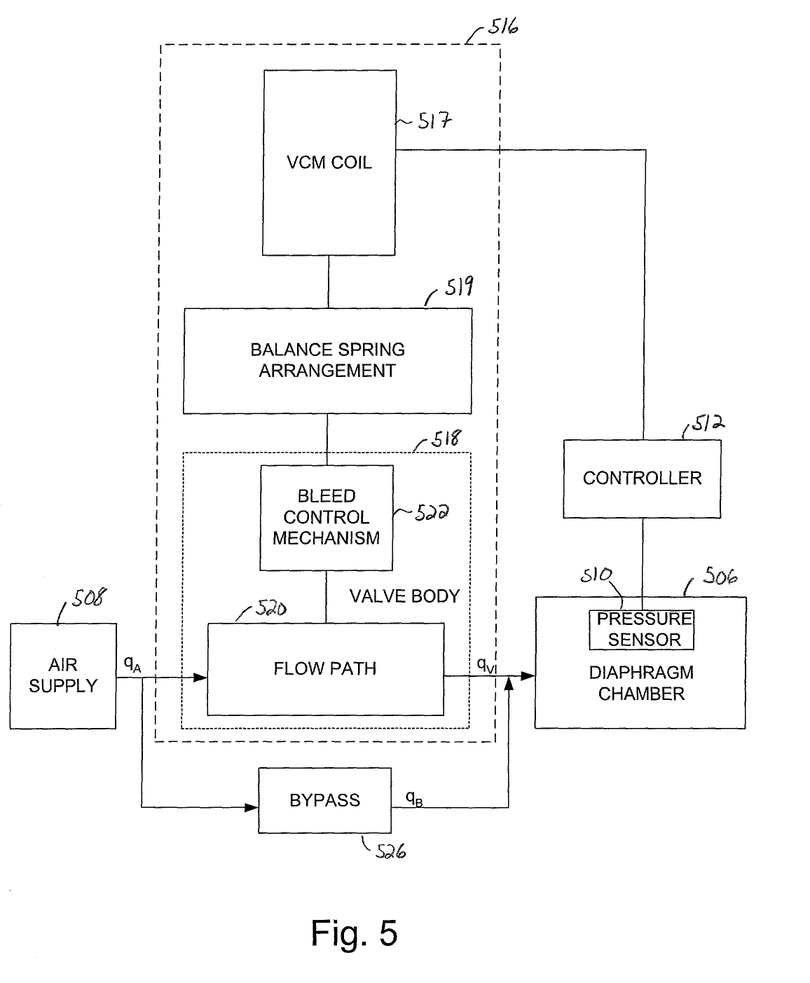

Valve mechanism 416 may include substantially any type of valve. One particular valve which is suitable for use as a part of vibration control system 402, as well as vibration control system 302 of FIG. 3, will be described below with reference to FIG. 5. As shown, valve mechanism 416 includes a body 418 which defines a flow path 420. Flow path 420 is fluidly coupled on one end to air supply 408 through a flow restrictor 409, e.g., a fixed flow restrictor, and fluidly coupled on another end to diaphragm chamber 406, such that air may flow from air supply 408 to diaphragm chamber 406 through flow path 420. Body 418 also includes a bleed control mechanism 422 which may include a bleed control ball that may at least partially block off an opening, e.g., funnel, coupled to flow path 420 to control the amount of air flow through flow path 420. Bleed control ball may also be arranged to block off essentially no flow, i.e., bleed control mechanism 422 may bleed off a substantially minimum amount of air with respect to the dimensions of flow path 420.

Like flow path 420, a bypass mechanism 426 also effectively couples air supply 408 to diaphragm chamber 406. Bypass mechanism 426 provides a path through which air may flow that is substantially parallel to flow path 420. Flow restrictor 409 is typically configured to cause air to flow through bypass mechanism 426. That is, flow restrictor 409 is arranged to restrict air flow through valve mechanism 416. Bypass mechanism 426 includes a valve 428 which enables an amount of flow which passes into diaphragm chamber 406 through bypass mechanism 426 to be controlled. Bypass mechanism 426 may generally include pipes which are fluidly coupled through valve 428. It should be appreciated that the flow capacity of the pipes themselves may be selected based on parameters such as, for example, the maximum ambient pressure which may be maintained in diaphragm chamber 406.

Valve 428, which may be a needle valve, may be adjusted to increase or to decrease the volume of air which flows through bypass mechanism 426 or, more specifically, through an outlet of valve 428. In other words, valve 428 may alter the flow capacity of bypass mechanism 426. Typically, valve 428 may be adjusted or calibrated, e.g., manually adjusted, before vibration control system 402 is put into use. That is, valve 428 may be set such that air flow through valve 428 is sufficient to substantially maintain an ambient pressure level within diaphragm chamber 406. In general, the flow capacity of bypass mechanism 426 is at least an order of magnitude higher than the flow capacity associated with valve mechanism 416. When changes to the pressure level within diaphragm chamber 406 are needed, as for example when a slight increase in the pressure level in diaphragm chamber 406 is needed, controller 412 may cause bleed control mechanism 422 to be adjusted in order to change the overall amount of air flow into diaphragm chamber 406.

A valve mechanism such as valve mechanism 416 of FIG. 4 maybe substantially any suitable valve which is controllable and includes a bleed control mechanism. One suitable valve is the T5200-90 valve available from Fairchild Industrial, Inc., of Winston-Salem, N.C. With reference to FIG. 5, one valve mechanism which is suitable for use with a bypass mechanism in a vibration control system will be described in accordance with an embodiment of the present invention. A valve mechanism 516 includes a voice coil motor (VCM) coil 517, a valve body 518, and a balance spring arrangement 519.

Coil 517 is controlled by a controller 512 that receives signals from a pressure sensor 510 which monitors the pressure level in a diaphragm chamber 506. When controller 512 attempts to increase air flow through flow path 520, controller causes coil 517 to close down on a bleed control mechanism 522 that, along with a flow path 520, is a part of valve body 518. Coil 517 enables bleed control mechanism 522 to be closed down, or opened up, relatively quickly. Hence, coil 517 provides the ability to change the amount of flow through flow path 520 without a significant delay, and the pressure level within diaphragm chamber 506 may reach a desired level substantially without delay.

Coil 517 cooperates with a flexure that is a part of balance spring arrangement 519 to provide forces which balance forces applied by coil 517 on a balance ball that is a part of bleed control mechanism 522. Balance spring arrangement 519 also serves to prevent the balance ball from being “blown” out of the funnel or channel in which it is generally positioned. Balance spring arrangement 519 generally includes two or more pre-loaded springs which are arranged against each other such that the force between the springs is balanced.

Bleed control mechanism 522 is arranged to cut-off or constrict at least some flow from an air supply 508 before the flow reaches diaphragm chamber 506. Specifically, the flow rate of air from air supply, i.e., q_{A}, is controlled by controller 512 using valve mechanism 516 to effectively reduce the flow rate of air passing out of flow path 520 of valve mechanism 520, i.e., qᵥ, to be at a level that is substantially lower than q_{A}. By opening up bleed control mechanism 522, e.g., by raising a bleed control ball further up with respect to a funnel arrangement by providing less voltage through coil 517, qᵥ may be decreased. Alternatively, by closing down bleed control mechanism 522, e.g., by dropping the bleed control ball further into the funnel arrangement to further obstruct flow out of the funnel arrangement by providing more voltage through coil 517, qᵥ may be increased.

Air flow from air supply 508, in addition to passing through flow path 520 of valve mechanism 516, passes through a bypass 526. Bypass 526 may, as described above with respect to FIG. 4, include a needle valve which serves as a flow control valve which controls the flow of air through bypass 526. The flow rate of air into bypass 526 is q_{A}, and the flow rate of air out of bypass 526 is a flow rate q_{B}. As will be appreciated by those skilled in the art, q_{B} is generally less than q_{A}, although q_{B} may be substantially equal to q_{A} in some cases. In the described embodiment, q_{B} is a substantially higher flow rate than qᵥ, e.g., q_{B} is an order of magnitude greater than qᵥ. As previously discussed, q_{B} may be varied by adjusting the valve included in bypass 526.

In general, the configuration of a bypass is selected prior to beginning use of a diaphragm chamber. By way of example, when a bypass is a pipe and does not include a valve, the dimensions of a conduit are selected before the diaphragm chamber is used. Alternatively, when the bypass includes a valve such as a needle valve, the needle valve is set to a selected position, e.g., the needle may be at least partially opened, prior to using the diaphragm chamber.

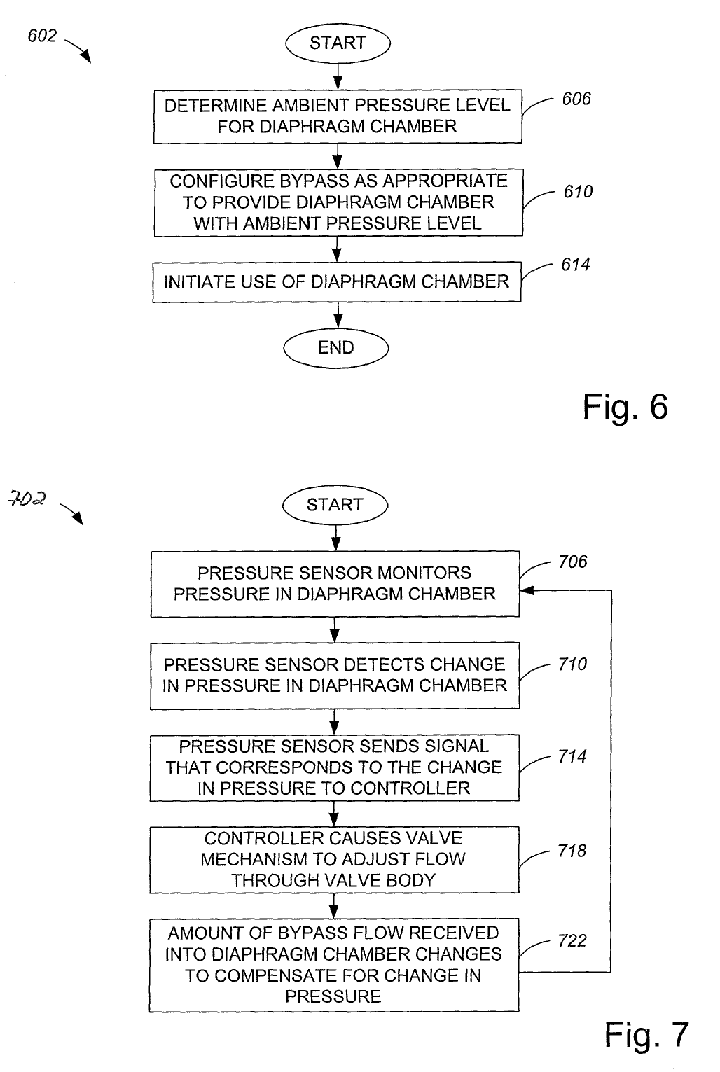

Referring next to FIG. 6, one method of configuring a vibration control system that includes a diaphragm chamber will be described in accordance with an embodiment of the present invention. A process 602 of configuring a vibration control system begins at step 606 in which an ambient pressure level within the diaphragm chamber is determined. The ambient pressure level within the diaphragm chamber is the approximate pressure level which is to be maintained in the diaphragm chamber, under most circumstances, when the diaphragm chamber is in use. In one embodiment, the ambient pressure level is the pressure level that is to be maintained in the diaphragm chamber to substantially compensate for expected vibrations which may affect a device, e.g., a photolithography machine, which is positioned on the diaphragm chamber. It should be appreciated that the pressure level within the diaphragm chamber may fluctuate around the desired ambient pressure level, as for example when more pressure is needed to compensate for a particular mode of vibration which is temporarily experienced with respect to the vibration control system.

Once the pressure level which is generally to be maintained within the diaphragm chamber is determined, the bypass in the vibration system, e.g., bypass 326 of FIG. 3 or bypass 426 of FIG. 4, is configured in step 610. Configuring the bypass generally involves either choosing or setting the bypass as appropriate such that the bypass may facilitate maintaining the chosen ambient pressure level within the diaphragm chamber. For an embodiment in which the bypass may be a conduit, configuring the bypass may include choosing a conduit that is sized to effectively create a flow rate that is suitable for maintaining the ambient pressure level within the diaphragm chamber from the flow rate of air supplied by the air supply. Alternatively, as previously discussed, for an embodiment in which the bypass includes a valve, the valve may be set to create a desired flow rate or volume.

After the bypass is configured in step 610, the diaphragm chamber may be initiated for use in step 614, and the set up of a vibration control system is completed. Initiating the diaphragm chamber or, more generally, the overall vibration control system, for use may include calibrating a pressure sensor which reads the pressure in the diaphragm chamber, as well as fine tuning a valve in the bypass.

With reference to FIG. 7, the operation of a vibration control system will be described in accordance with an embodiment of the present invention. A process 702 which occurs in a vibration control system during operation generally enables the pressure level within a diaphragm chamber to reach a desired equilibrium with respect to a device supported on the diaphragm of the diaphragm chamber. In other words, the vibration control system is arranged to vary the pressure level in a diaphragm chamber as needed to prevent the device supported by the diaphragm of the diaphragm chamber for experiencing vibration.

Process 702 begins at step 706 in which a pressure sensor monitors the pressure level in the diaphragm chamber. When the pressure sensor detects a change in the pressure level in step 710, the pressure sensor sends a signal that corresponds to the change in pressure in step 714. The signal sent by the pressure sensor is generally a data signal that is sent to a controller that uses signals from the pressure sensor to control the operation of the valve mechanism, as discussed above. The controller, which may be substantially any suitable controller, causes the valve mechanism to adjust flow through a flow path, e.g., flow body 318 of FIG. 3, in step 718.

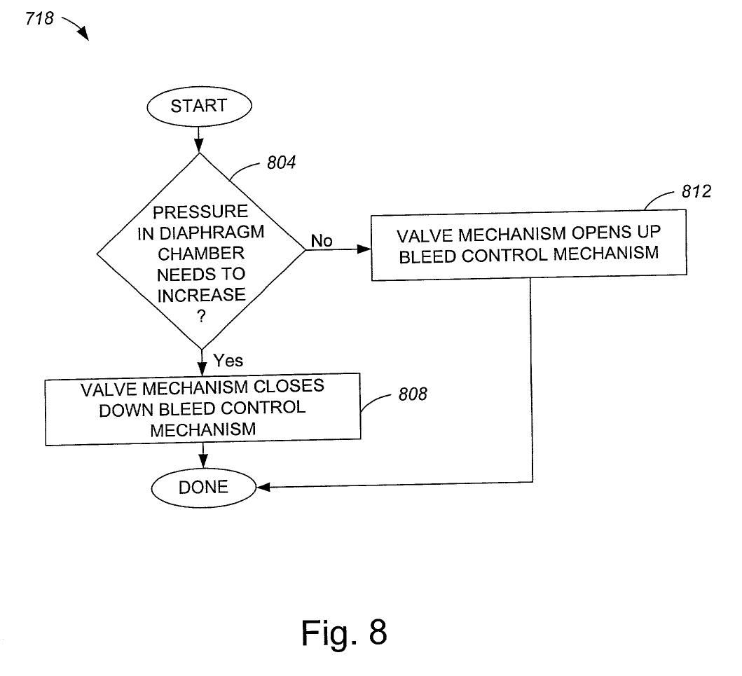

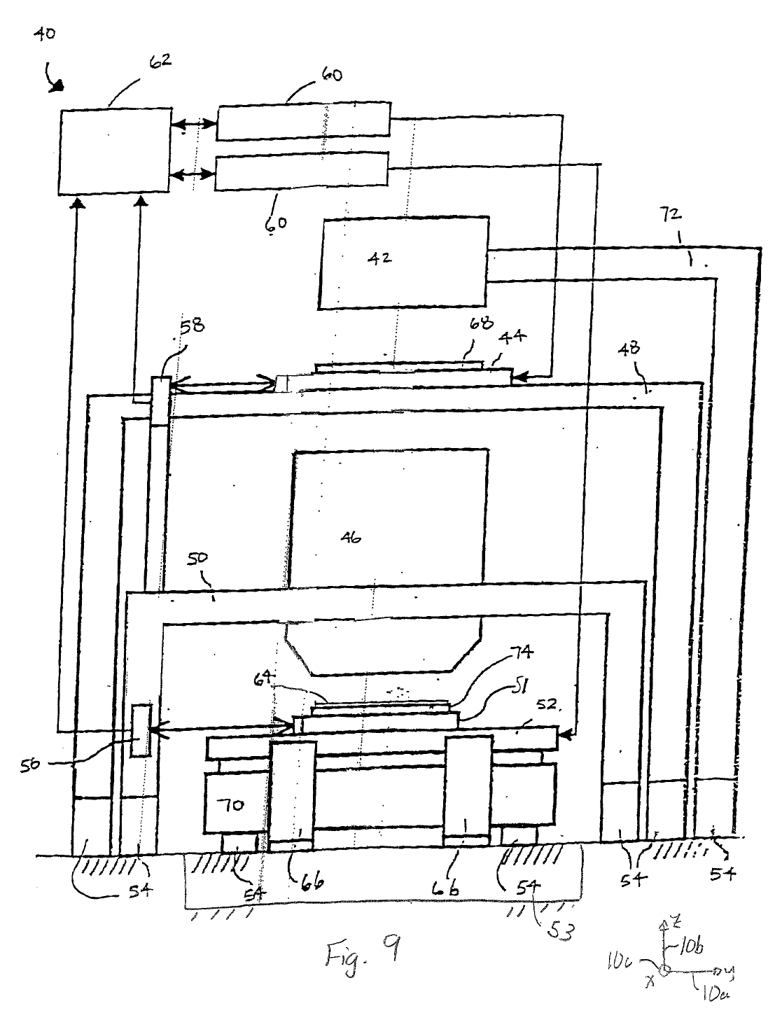

In one embodiment, as shown in FIG. 5, the controller may adjust the voltage and the current sent through a VCM coil to cause the flow of air through the valve mechanism to change. Specifically, in the described embodiment, the controller may cause the voltage and current passing through the VCM coil to move a bleed control mechanism, which alters the amount of air that flows through the valve mechanism, as will be discussed below with respect to FIG. 8.

Adjusting the amount of flow which passes through the valve mechanism typically alters the pressure within the diaphragm chamber by altering the amount of air that flows through a bypass. Altering the pressure may compensate for vibrations, such as those with a frequency of greater than approximately one hertz (Hz), relatively quickly, i.e., with a relatively fast response time. As such, in step 722, the amount of flow through the bypass, e.g., bypass flow, that is received into the diaphragm chamber changes in response to adjustments made to the flow through the valve mechanism. The change in the amount of flow received into the diaphragm chamber typically raises or lowers, as appropriate, the pressure level in the diaphragm chamber. Once the amount of flow received in the diaphragm chamber is changed, the pressure sensor monitors the pressure level in the diaphragm chamber in step 706 and detects changes in the pressure level in step 710.

When a pressure sensor monitors the pressure level in the diaphragm chamber, once vibrations are successfully damped out, feedback to a controller from the pressure sensor will generally not cause the controller to alter the configuration of a valve mechanism. However, when the pressure monitor detects a change in pressure within the diaphragm chamber, e.g., as a result of a change in the modes of vibration or the frequency of vibration experienced by the diaphragm chamber, the pressure monitor may send a feedback signal or a feedforward signal to the controller that indicates that a change in the configuration of the valve mechanism may be desired. Once the signal is received by the controller, the controller causes the valve mechanism to make adjustments to settings as necessary.

FIG. 8 is a process flow diagram which illustrates the steps associated with adjusting flow through a valve mechanism, i.e., step 718 of FIG. 7, which occur in a vibration control system in accordance with an embodiment of the present invention. When a controller receives a signal which indicates that changes to the settings of a valve mechanism may return the pressure level in a diaphragm chamber to a desired level, the controller uses the signal to determine how the valve is to be controlled in order to achieve the desired effect, e.g., in order to alter the pressure level in the diaphragm chamber appropriately. In step 804, a determination is made as to whether the current pressure level in the diaphragm chamber needs to be increased. That is, it is determined whether the pressure sensor has sensed that the existing pressure level in the diaphragm chamber is lower than desired.

If it is determined that the current pressure level in the diaphragm chamber needs to increase, then the indication is that more flow of air into the diaphragm chamber is needed. As such, process flow moves from step 804 to step 808 in which the controller causes the valve mechanism to reduce the amount of air that is bled off from the valve mechanism. In the described embodiment, reducing the amount of air that is bled off from the valve mechanism includes causing a bleed control ball to be positioned further down into a funnel arrangement such that flow through the funnel arrangement around the bleed control ball is further restricted. By reducing the amount of air that is bled off from the valve mechanism, more air is allowed to pass through the valve mechanism and into the diaphragm chamber. Hence, the pressure level in the diaphragm chamber may be increased. Once the valve control mechanism closes down the bleed control mechanism to decrease the amount of air that is bled out of the valve mechanism, the process of adjusting the amount of flow through a valve mechanism is completed.

Alternatively, if it is determined in step 804 that the current pressure level in the diaphragm chamber does not need to be increased, then the implication is that the pressure level is to be decreased. That is, the indication is that the pressure level in the diaphragm chamber is too high. Accordingly, in step 812, the controller causes the valve mechanism to open up the bleed control mechanism. Opening up the bleed control mechanism, in the described embodiment, includes retracting the bleed control ball with respect to a funnel arrangement such that more flow, or less restricted flow, may occur through the funnel arrangement and around the bleed control ball. After the bleed control mechanism is further opened, the process of adjusting the amount of flow through a valve mechanism is completed.

Precision instruments such as photolithography machines may be subjected to vibrations. The vibrations in a photolithography machine or apparatus may be dampened through the use of a diaphragm chamber that is controlled by a controller with a valve bypass. With reference to FIG. 9, a photolithography apparatus which includes stage devices and may have vibrations dampened by a diaphragm chamber will be described in accordance with an embodiment of the present invention. A photolithography apparatus (exposure apparatus) 40 includes a wafer positioning stage 52 that may be driven by a planar motor (not shown), as well as a wafer table 51 that is magnetically coupled to wafer positioning stage 52 by utilizing an EI-core actuator.

The planar motor which drives wafer positioning stage 52 generally uses an electromagnetic force generated by magnets and corresponding armature coils arranged in two dimensions. A wafer 64 is held in place on a wafer holder 74 which is coupled to wafer table 51. Wafer positioning stage 52 is arranged to move in multiple degrees of freedom, e.g., between three to six degrees of freedom, under the control of a control unit 60 and a system controller 62. The movement of wafer positioning stage 52 allows wafer 64 to be positioned at a desired position and orientation relative to a projection optical system 46.

Wafer table 51 may be levitated in a z-direction 10b by any number of voice coil motors (not shown), e.g., three voice coil motors. In the described embodiment, at least three magnetic bearings (not shown) couple and move wafer table 51 along a y-axis 10a. The motor array of wafer positioning stage 52 is typically supported by a base 70. Base 70 is supported to a diaphragm chamber 53, e.g., diaphragm chamber 406 of FIG. 4, via isolators 54. Diaphragm chamber 53 is arranged to dampen vibrations caused by the motor array of wafer positioning stage 52. Reaction forces generated by motion of wafer stage 52 may be mechanically released to a ground surface through a frame 66 and diaphragm chamber 53. One suitable frame 66 is described in JP Hei 8-166475 and U.S. Pat. No. 5,528,118, which are each herein incorporated by reference in their entireties.

An illumination system 42 is supported by a frame 72. Frame 72 is supported to the ground via isolators 54. Illumination system 42 includes an illumination source, and is arranged to project a radiant energy, e.g., light, through a mask pattern on a reticle 68 that is supported by and scanned using a reticle stage 44 which includes a coarse stage and a fine stage. Reticle stage 44 is supported on a reticle stage frame 48. The radiant energy is focused through projection optical system 46, which is supported on a projection optics frame 50 and may be released to the ground through isolators 54. Suitable isolators 54 include those described in JP Hei 8-330224 and U.S. Pat. No. 5,874,820, which are each incorporated herein by reference in their entireties. Instead of providing diaphragm chamber 53, each isolator shown in FIG. 8 may be installed with respect to a diaphragm chamber 406 of FIG. 4 respectively and controlled to dampen vibrations.

A first interferometer 56 is supported on projection optics frame 50, and functions to detect the position of wafer table 51. Interferometer 56 outputs information on the position of wafer table 51 to system controller 62. In one embodiment, wafer table 51 has a force damper which reduces vibrations associated with wafer table 51 such that interferometer 56 may accurately detect the position of wafer table 51. A second interferometer 58 is supported on projection optics frame 50, and detects the position of reticle stage 44 which supports a reticle 68. In one embodiment, vibrations of reticle stage 44 may be dampened using any of the force dampers described above. Interferometer 58 also outputs position information to system controller 62.

It should be appreciated that there are a number of different types of photolithographic apparatuses or devices. For example, photolithography apparatus 40, or an exposure apparatus, may be used as a scanning type photolithography system which exposes the pattern from reticle 68 onto wafer 64 with reticle 68 and wafer 64 moving substantially synchronously. In a scanning type lithographic device, reticle 68 is moved perpendicularly with respect to an optical axis of a lens assembly (projection optical system 46) or illumination system 42 by reticle stage 44. Wafer 64 is moved perpendicularly to the optical axis of projection optical system 46 by a wafer positioning stage 52. Scanning of reticle 68 and wafer 64 generally occurs while reticle 68 and wafer 64 are moving substantially synchronously.

Alternatively, photolithography apparatus or exposure apparatus 40 may be a step-and-repeat type photolithography system that exposes reticle 68 while reticle 68 and wafer 64 are stationary. In one step and repeat process, wafer 64 is in a substantially constant position relative to reticle 68 and projection optical system 46 during the exposure of an individual field. Subsequently, between consecutive exposure steps, wafer 64 is consecutively moved by wafer positioning stage 52 perpendicularly to the optical axis of projection optical system 46 and reticle 68 for exposure. Following this process, the images on reticle 68 may be sequentially exposed onto the fields of wafer 64 so that the next field of semiconductor wafer 64 is brought into position relative to illumination system 42, reticle 68, and projection optical system 46.

It should be understood that the use of photolithography apparatus or exposure apparatus 40, as described above, is not limited to being used in a photolithography system for semiconductor manufacturing. For example, photolithography apparatus 40 may be used as a part of a liquid crystal display (LCD) photolithography system that exposes an LCD device pattern onto a rectangular glass plate or a photolithography system for manufacturing a thin film magnetic head. Further, photolithography apparatus 40 which has vibrations that are dampened by diaphragm chamber 53 may also be a part of a proximity photolithography system that exposes a mask pattern by closely locating a mask and a substrate without the use of a lens assembly.

The illumination source of illumination system 42 may be g-line (436 nanometers (nm)), i-line (365 nm), a KrF excimer laser (248 nm), a ArF excimer laser (193 nm), and an F₂-type laser (157 nm). Alternatively, illumination system 42 may also use charged particle beams such as x-ray and electron beams. For instance, in the case where an electron beam is used, thermionic emission type lanthanum hexaboride (LaB₆) or tantalum (Ta) may be used as an electron gun. Furthermore, in the case where an electron beam is used, the structure may be such that either a mask is used or a pattern may be directly formed on a substrate without the use of a mask.

With respect to projection optical system 46, when far ultra-violet rays such as an excimer laser are used, glass materials such as quartz and fluorite that transmit far ultraviolet rays is preferably used. When either an F₂-type laser or an x-ray is used, projection optical system 46 may be either catadioptric or refractive (a reticle may be of a corresponding reflective type), and when an electron beam is used, electron optics may comprise electron lenses and deflectors. As will be appreciated by those skilled in the art, the optical path for the electron beams is generally in a vacuum.

In addition, with an exposure device that employs vacuum ultra-violet (VUV) radiation of a wavelength that is approximately 200 nm or lower, use of a catadioptric type optical system may be considered. Examples of a catadioptric type of optical system include, but are not limited to, those described in Japan Patent Application Disclosure No. 8-171054 published in the Official gazette for Laid-Open Patent Applications and its counterpart U.S. Pat. No. 5,668,672, as well as in Japan Patent Application Disclosure No. 10-20195 and its counterpart U.S. Pat. No. 5,835,275, which are all incorporated herein by reference in their entireties. In these examples, the reflecting optical device may be a catadioptric optical system incorporating a beam splitter and a concave mirror. Japan Patent Application Disclosure (Hei) No. 8-334695 published in the Official gazette for Laid-Open Patent Applications and its counterpart U.S. Pat. No. 5,689,377, as well as Japan Patent Application Disclosure No. 10-3039 and its counterpart U.S. Pat. No. 5,892,117, which are all incorporated herein by reference in their entireties. These examples describe a reflecting-refracting type of optical system that incorporates a concave mirror, but without a beam splitter, and may also be suitable for use with the present invention.

Further, in photolithography systems, when linear motors (see U.S. Pat. Nos. 5,623,853 or 5,528,118, which are each incorporated herein by reference in their entireties) are used in a wafer stage or a reticle stage, the linear motors may be either an air levitation type that employs air bearings or a magnetic levitation type that uses Lorentz forces or reactance forces. Additionally, the stage may also move along a guide, or may be a guideless type stage which uses no guide.

Alternatively, a wafer stage or a reticle stage may be driven by a planar motor which drives a stage through the use of electromagnetic forces generated by a magnet unit that has magnets arranged in two dimensions and an armature coil unit that has coil in facing positions in two dimensions. With this type of drive system, one of the magnet unit or the armature coil unit is connected to the stage, while the other is mounted on the moving plane side of the stage.

Movement of the stages as described above generates reaction forces which may affect performance of an overall photolithography system. Reaction forces generated by the wafer (substrate) stage motion may be mechanically released to the floor or ground by use of a frame member as described above, as well as in U.S. Pat. No. 5,528,118 and published Japanese Patent Application Disclosure No. 8-166475. Additionally, reaction forces generated by the reticle (mask) stage motion may be mechanically released to the floor (ground) by use of a frame member as described in U.S. Pat. No. 5,874,820 and published Japanese Patent Application Disclosure No. 8-330224, which are each incorporated herein by reference in their entireties.

As described above, a photolithography system according to the above-described embodiments may be built by assembling various subsystems in such a manner that prescribed mechanical accuracy, electrical accuracy, and optical accuracy are maintained. In order to maintain the various accuracies, prior to and following assembly, substantially every optical system may be adjusted to achieve its optical accuracy. Similarly, substantially every mechanical system and substantially every electrical system may be adjusted to achieve their respective desired mechanical and electrical accuracies. The process of assembling each subsystem into a photolithography system includes, but is not limited to, developing mechanical interfaces, electrical circuit wiring connections, and air pressure plumbing connections between each subsystem. There is also a process where each subsystem is assembled prior to assembling a photolithography system from the various subsystems. Once a photolithography system is assembled using the various subsystems, an overall adjustment is generally performed to ensure that substantially every desired accuracy is maintained within the overall photolithography system. Additionally, it may be desirable to manufacture an exposure system in a clean room where the temperature and humidity are controlled.

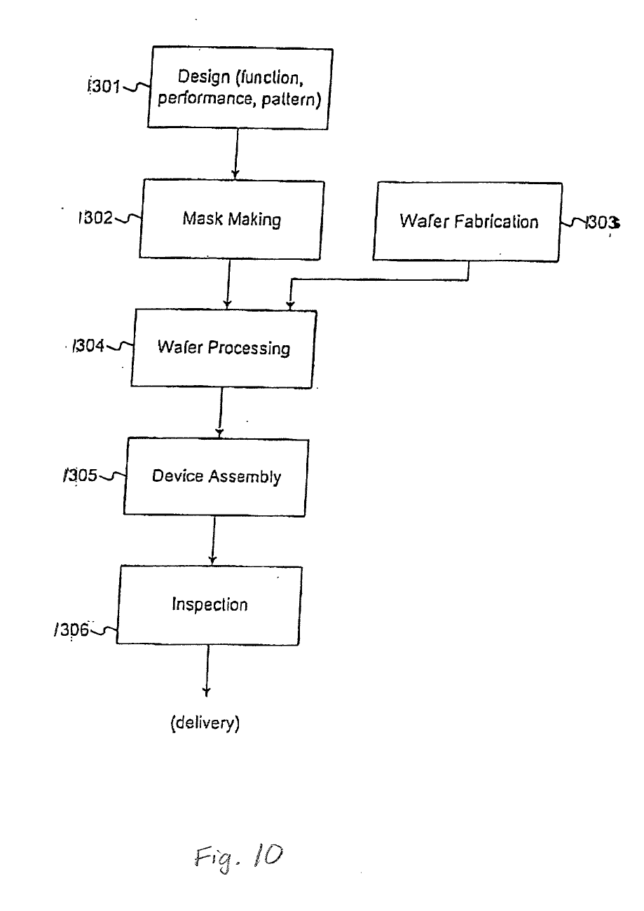

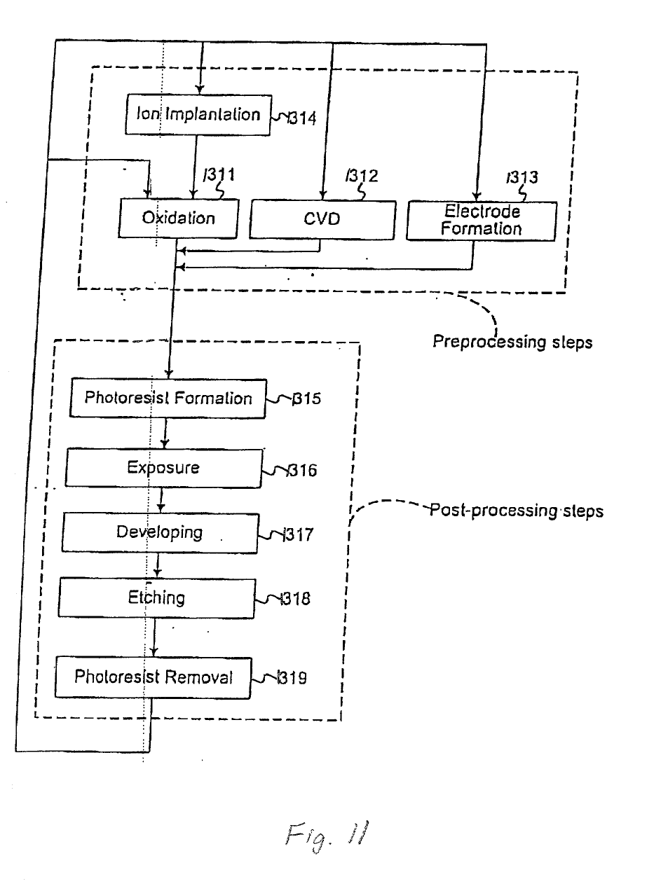

Further, semiconductor devices may be fabricated using systems described above, as will be discussed with reference to FIG. 10. The process begins at step 1301 in which the function and performance characteristics of a semiconductor device are designed or otherwise determined. Next, in step 1302, a reticle (mask) in which has a pattern is designed based upon the design of the semiconductor device. It should be appreciated that in a parallel step 1303, a wafer is made from a silicon material. The mask pattern designed in step 1302 is exposed onto the wafer fabricated in step 1303 in step 1304 by a photolithography system that includes a reticle scanning stage and has vibrations that are dampened by a diaphragm chamber as described above. One process of exposing a mask pattern onto a wafer will be described below with respect to FIG. 11. In step 1305, the semiconductor device is assembled. The assembly of the semiconductor device generally includes, but is not limited to, wafer dicing processes, bonding processes, and packaging processes. Finally, the completed device is inspected in step 1306.

FIG. 11 is a process flow diagram which illustrates the steps associated with wafer processing in the case of fabricating semiconductor devices in accordance with an embodiment of the present invention. In step 1311, the surface of a wafer is oxidized. Then, in step 1312 which is a chemical vapor deposition (CVD) step, an insulation film may be formed on the wafer surface. Once the insulation film is formed, in step 1313, electrodes are formed on the wafer by vapor deposition. Then, ions may be implanted in the wafer using substantially any suitable method in step 1314. As will be appreciated by those skilled in the art, steps 1311-1314 are generally considered to be preprocessing steps for wafers during wafer processing. Further, it should be understood that selections made in each step, e.g., the concentration of various chemicals to use in forming an insulation film in step 1312, maybe made based upon processing requirements.

At each stage of wafer processing, when preprocessing steps have been completed, post-processing steps may be implemented. During post-processing, initially, in step 1315, photoresist is applied to a wafer. Then, in step 1316, an exposure device may be used to transfer the circuit pattern of a reticle to a wafer. Transferring the circuit pattern of the reticle of the wafer generally includes scanning a reticle scanning stage which may, in one embodiment, be positioned on a surface of a diaphragm chamber to reduce vibrations associated with the reticle scanning stage.

After the circuit pattern on a reticle is transferred to a wafer, the exposed wafer is developed in step 1317. Once the exposed wafer is developed, parts other than residual photoresist, e.g., the exposed material surface, may be removed by etching in step 1318. Finally, in step 1319, any unnecessary photoresist that remains after etching may be removed. As will be appreciated by those skilled in the art, multiple circuit patterns may be formed through the repetition of the preprocessing and post-processing steps.

Although only a few embodiments of the present invention have been described, it should be understood that the present invention may be embodied in many other specific forms without departing from the spirit or the scope of the present invention. By way of example, an AVIS has generally been described as including a chamber and a diaphragm that may be formed from fabric and rubber. It should be appreciated, however, that a chamber with a diaphragm is but one example of an AVIS to which the present invention may be applied. By way of example, the present invention may be applied to a chamber with a bellows, a chamber with a piezo-electric component, or a chamber with substantially any relatively flexible membrane.

While the use of a needle valve has been described as being suitable for allowing a bypass mechanism to be readily configured to meet different flow requirements or different pressure requirements, other types of valves or mechanisms may be used in lieu of a needle valve to facilitate the configuration of a bypass mechanism. In addition, various nozzles may also be used either in place of or in conjunction with a conduit to form a suitable bypass mechanism. It should be appreciated that in some instances, a flow expander may also be used as a part of a bypass mechanism.

As discussed above, a bypass may generally include a pipe or a conduit, e.g., a rubber pipe or a plastic pipe, which has a substantially circular cross-section. Specifically, a bypass which does not include a valve such as a needle valve may be formed from a pipe. A bypass which includes a valve may also be formed from pipes which are coupled to the valve such that the valve controls the flow with respect to the pipes, as mentioned above. It should be understood that a bypass may also have a variety of other configurations. Suitable configurations include, but are not limited to, a configuration in which a bypass includes conduits, “ducts,” or other types of tubes that have cross-sectional areas which may be polygonally shaped, e.g., square shaped, or irregularly shaped.

A pressure sensor has been described as being suitable for use in alerting or otherwise signaling a controller to alter the performance of a valve mechanism. In general, however, other types of sensors may be suitable for use in providing an input, e.g., feedforward or feedback control signal, that is processed by the controller. For example, a force transducer or a vibration sensor may be used to provide input to the controller without departing from the spirit or the scope of the present invention.

In one embodiment, rather than trying to maintain the pressure level in a diaphragm chamber at a particular level, a controller may cause a valve mechanism to change its settings such that the pressure level in the diaphragm chamber may either be raised or lowered to a new desired level. By way of example, a pressure sensor may cooperate with a vibration sensor to sense when vibrations experienced by a device supported by the diaphragm sensor change to a significant extent. When changes in a vibration level are significant, then it may be desirable to change the desired or ambient pressure level in the diaphragm sensor to compensate for the new vibration level.

While a bypass mechanism is suitable for use in a system which uses air flow or gas flow, a bypass mechanism may generally be used in any system in which the flow associated with a controlled valve is effectively to be increased. In other words, a bypass mechanism may be implemented for use in substantially any system in which the performance of a valve is to be augmented to provide a relatively quick response to a desired change in a flow rate. For example, a bypass mechanism may be implemented to serve as a shunt in a system which uses fluid flow.

Generally, the steps associated with the various methods and processes of the present invention may vary. Steps may be altered, added, removed, and reordered without departing from the spirit or the scope of the present invention. Therefore, the present examples are to be considered as illustrative and not restrictive, and the invention is not to be limited to the details given herein, but may be modified within the scope of the appended claims.

What is claimed is:

1. An active vibration isolation system, the active vibration isolation system being arranged to reduce the vibrations experienced by a mass, the active vibration isolation system comprising:
a chamber, the chamber including a surface that is arranged to support the mass;
a control device, the control device being arranged to monitor a pressure level within the chamber; the control device further being arranged to generate a control signal;
a valve mechanism, the valve mechanism including a first flow path, the first flow path being in fluid communication with the chamber to enable fluid to flow between the first flow path and the chamber, the valve mechanism being arranged to alter a flow capacity of the first flow path in response to the control signal; and
a bypass mechanism, the bypass mechanism defining a second flow path, the second flow path being in fluid communication with the chamber to enable fluid to flow through the second flow path and into the chamber, wherein the second flow path is substantially parallel to the first flow path to enable parallel fluid flow to occur in the second flow path and the first flow path, wherein a flow capacity of the second flow path is substantially greater than the flow capacity of the first flow path.

2. An active vibration isolation system according to claim 1 wherein the bypass mechanism includes a flow control device, the flow control device being arranged to alter the flow capacity of the second flow path.

3. An active vibration isolation system according to claim 1 wherein the fluid that flows between the first flow path and the chamber and the fluid that flows through the second flow path and into the chamber cooperate to maintain the pressure level within the chamber at a predetermined level.

4. An active vibration isolation system according to claim 1 wherein the valve mechanism includes a bleed control mechanism, the bleed control mechanism being coupled to the first flow path, and wherein the valve mechanism is arranged to alter the flow capacity of the first flow path through the bleed control mechanism.

5. An active vibration isolation system according to claim 4 wherein the valve mechanism controls an amount of fluid removed from the first flow path through the bleed control mechanism.

6. An active vibration isolation system according to claim 1 wherein the surface is a diaphragm.

7. An active vibration isolation system according to claim 1 further including an fluid supply, the fluid supply being in fluid communication with the first flow path, the fluid supply further being in fluid communication with the second flow path, wherein the fluid supply is arranged to provide the fluid that flows between the first flow path and the chamber and the fluid that flows through the second flow path and into the chamber.

8. A control system, the control system comprising:
a fluid supply, the fluid supply being arranged to supply fluid;
a device, the device including a device inlet and a chamber, the device inlet being arranged to provide the fluid into the chamber to maintain a pressure within the chamber;
a controller mechanism, the controller mechanism being arranged to monitor the pressure within the chamber;
a valve mechanism, the valve mechanism being in communication with the controller mechanism, the valve mechanism being fluidly coupled to the fluid supply, the valve mechanism further being fluidly coupled to the device, wherein the controller mechanism is arranged to at least partially control flow of the fluid through the valve mechanism; and
a bypass mechanism, the bypass mechanism being fluidly coupled to the fluid supply, wherein a flow rate of fluid passing from the bypass mechanism to the device is substantially higher than a flow rate of fluid passing from the valve mechanism to the device.

9. A control system according to claim 8, wherein the bypass mechanism includes a flow adjuster, the flow adjuster being arranged to control the flow rate of the fluid passing from the bypass mechanism to the device.

10. A control system according to claim 9 wherein the flow adjuster is a valve.

11. A control system according to claim 8 wherein the valve mechanism includes a flow path, and the controller mechanism is arranged to control the valve mechanism to increase the flow of fluid through the flow path.

12. A control system according to claim 11 wherein the controller mechanism is further arranged to control the valve mechanism to decrease the flow of fluid through the flow path.

13. A control system according to claim 8 wherein the controller mechanism is arranged to at least partially control flow of the fluid through the valve mechanism to maintain the pressure within the chamber.

13. A stage assembly positioned on the chamber, wherein vibrations of the stage assembly are controlled by the control system of claim 8.

15. An exposure apparatus comprising a stage assembly positioned on the chamber, wherein vibrations of the exposure apparatus are controlled by the control system of claim 8.

16. A device manufactured with the exposure apparatus of claim 15.

17. A wafer on which an image has been formed by the exposure apparatus of claim 15.

18. A method for operating a vibration control device, the vibration control device including a chamber, a control device, a valve mechanism, and a bypass, the method comprising:
a) providing a first amount of fluid to the chamber through the valve mechanism;
b) providing a second amount of fluid to the chamber through the bypass, wherein the second amount of fluid is substantially greater than the first amount of fluid;
c) determining when a change in a pressure level within the chamber has been detected using the control device;
d) causing the valve mechanism to adjust the first amount of fluid using the control device when it is determined that the change in the pressure level within the chamber has been detected;
e) providing the adjusted first amount of fluid to the chamber through the valve mechanism to compensate for the change in the pressure level within the chamber when it is determined that the change in the pressure level within the chamber has been detected; and
repeating b)-e).

19. A method for operating a vibration control device as recited in claim 18 wherein the second amount of fluid provided to the chamber is provided substantially continuously.

20. A method for operating a vibration control device as recited in claim 19 wherein fluid is provided to the chamber through the valve mechanism substantially continuously, wherein the fluid provided to the chamber through the valve mechanism is one of the first amount of fluid and the adjusted first amount of fluid.

21. A method for operating a vibration control device as recited in claim 18 wherein the valve mechanism includes a bleed control mechanism and a coil, the coil being communicably coupled to the control device, the coil further being coupled to the bleed control mechanism, and causing the valve mechanism to adjust the first amount of fluid using the control device includes causing the coil to alter an orientation of the bleed control mechanism to control an amount of fluid that is to alter the first amount of fluid.

22. A method for operating a vibration control device as recited in claim 21 determining when a change in the pressure level within the chamber has been detected using the control device includes determining whether the pressure level within the chamber is to be increased, wherein when it is determined that the pressure level within the chamber is to be increased, causing the valve mechanism to adjust the first amount of fluid using the control device further includes:
causing the coil to increase an amount of obstruction associated with the bleed control mechanism, wherein increasing the amount of obstruction associated the bleed control mechanism increases the first amount of fluid that is provided to the chamber through the valve mechanism.

23. A method for operating a vibration control device as recited in claim 21 determining when a change in the pressure level within the chamber has been detected using the control device includes determining whether the pressure level within the chamber is to be decreased, wherein when it is determined that the pressure level within the chamber is to be decreased, causing the valve mechanism to adjust the first amount of fluid using the control device further includes:
causing the coil to decrease an amount of obstruction associated with the bleed control mechanism, wherein decreasing the amount of obstruction associated the bleed control mechanism decreases the first amount of fluid that is provided to the chamber through the valve mechanism.

24. A method for operating an exposure apparatus positioned on the chamber including the method for operating a vibration control device of claim 18.

25. A method for making an object including at least a photolithography process, wherein the photolithography process utilizes the method of operating an exposure apparatus of claim 24.

26. A method for making a wafer utilizing the method of operating an exposure apparatus of claim 24.

27. A method for operating a stage assembly positioned on the chamber, the method including the method for operating a vibration control device of claim 18.

28. A method for controlling a pressure within a chamber, the method comprising:
providing a first amount of fluid to the chamber through a first fluid path;
providing a second amount of fluid to the chamber through a second fluid path, wherein the second amount of fluid is substantially greater than the first amount of fluid;
detecting information related to a pressure level within the chamber; and
adjusting the first amount of fluid based on the information.

29. A method for controlling a pressure within a chamber as recited in claim 28 wherein the second amount of fluid provided to the chamber is provided substantially continuously.
